(19) United States
(12) Patent Application Publication
(10) Pub. No.: US 2025/0040008 A1
(43) Pub. Date: Jan. 30, 2025

(54) LIGHTING CONTROL DEVICE HAVING INCREASED OUTPUT VOLTAGE RANGE AND LIGHTING DEVICE INCLUDING THE SAME

(71) Applicant: KUM KYEONG LIGHTING CO., LTD., Busan (KR)

(72) Inventors: Dongwook LEE, Busan (KR); Namsun LEE, Seoul (KR)

(73) Assignee: KUM KYEONG LIGHTING CO., LTD., Busan (KR)

(21) Appl. No.: 18/784,865

(22) Filed: Jul. 25, 2024

(30) Foreign Application Priority Data
Jul. 26, 2023 (KR) 10-2023-0097246

(51) Int. Cl. H05B 45/14; H05B 45/325; H05B 45/3725

(52) U.S. Cl. CPC H05B 45/14; H05B 45/325; H05B 45/3725

(57) ABSTRACT

Disclosed is a lighting control device. The lighting control device connected to a lamp module and configured to control light emission of the lamp module includes a driver configured to receive input power, output output power to the lamp module, and adjust a magnitude of the output power according to the result of comparison between a feedback pin voltage applied to a feedback pin and a threshold voltage, a feedback voltage output unit configured to output a feedback voltage unrelated to the output power to the feedback pin, and a dimming controller configured to receive a dimming level signal and output a dimming control signal for controlling the brightness of the lamp module to the feedback pin based on a target dimming level corresponding to the dimming level signal and a current dimming level corresponding to a current brightness of the lamp module.

### TECHNICAL FIELD

The present disclosure relates to a lighting control device and a lighting device including the same, and to a lighting control device having an increased, that is, wide output voltage range, and a lighting device including the same.

### BACKGROUND ART

Recently, lighting devices have been replaced with a light emitting diode (LED) lighting including an LED element that may be implemented to have a relatively long lifetime, low consumed power, and high luminance instead of an incandescent or fluorescent lamp. A control device such as a converter for converting typical commercial power into rated power suitable for the LED lighting is required to drive the LED lighting.

Such a converter has a fixed output voltage range (e.g., DC 21 V to 29 V). Therefore, the output voltage range of the converter mounted on the lighting device should be designed and installed in advance to match the rated power of the connected LED lighting.

Meanwhile, due to a recent increase in the efficiency of the LED element, there has been recently a trend of converting conventional low-efficiency LED lighting into high-efficiency LED lighting. When the efficiency of the LED lighting increases, the rated power of the LED lighting for maintaining the same brightness decreases, and thus the LED lighting may not be operated by the conventional converter. As a result, the converter should be replaced inevitably.

Therefore, there is a need for a converter having a wide output voltage range in which the LED lighting having various rated powers may be controlled.

### SUMMARY OF INVENTION

### Technical Problem

The present disclosure is directed to providing a lighting control device having a wide output voltage range and a lighting device including the same, which may control a lamp module having various rated powers without separate setting.

### Solution to Problem

The lighting control device connected to a lamp module and configured to control light emission of the lamp module according to embodiments of the present disclosure includes a driver configured to receive input power, output output power to the lamp module, and adjust a magnitude of the output power according to the result of comparison between a feedback pin voltage applied to a feedback pin and a threshold voltage, a feedback voltage output unit configured to output a feedback voltage unrelated to the output power to the feedback pin, and a dimming controller configured to receive a dimming level signal and output a dimming control signal for controlling the brightness of the lamp module to the feedback pin based on a target dimming level corresponding to the dimming level signal and a current dimming level corresponding to a current brightness of the lamp module.

### Advantageous Effects of Invention

According to the embodiments of the present disclosure, the lighting control device and the lighting device including the same have a relatively wide output voltage range and thus can be applied to LED lighting having various rated powers.

Therefore, in the lighting control device according to the embodiments of the present disclosure, since the lamp module of the conventional lighting device may be replaced with the high-efficiency lamp module, even when the rated voltage is reduced, the replaced lamp module can be still normally controlled.

In addition, since the conventional lighting device installed in the field has various rated voltages (e.g., 17 V/21 V/25 V/28 V/30 V), there is inconvenience of having to operate and manage the inventory of the corresponding lighting control device for each lamp module or lighting device product and selecting and using the suitable lighting control device, but the lighting control device according to the embodiments of the present disclosure may be applied to all products regardless of a rated voltage and a product model.

### BRIEF DESCRIPTION OF DRAWINGS

FIG. 1 shows a lighting device according to embodiments of the present disclosure.

FIG. 2 shows a lighting control device according to the embodiments of the present disclosure.

FIG. 3 shows a driver according to the embodiments of the present disclosure.

FIG. 4 is a view for describing an operation of a feedback voltage output unit according to the embodiments of the present disclosure.

FIG. 5 is a view for describing an operation of a dimming controller according to the embodiments of the present disclosure.

FIG. 6 is a view for describing the effect of the lighting control device according to the embodiments of the present disclosure.

FIG. 7 shows a maximum output fixing unit according to the embodiments of the present disclosure.

FIG. 8 shows a minimum dimming unit and a zero dimming unit according to the embodiments of the present disclosure.

### DESCRIPTION OF EMBODIMENTS

Hereinafter, exemplary embodiments according to the present disclosure will be described in detail with reference to the accompanying drawings.

The embodiments are provided to more completely describe the present disclosure to those skilled in the art, and the following embodiments may be modified in various different forms, and the scope of the present disclosure is limited to the following embodiments. Rather, the embodiments are provided to make the disclosure more faithful and complete and fully convey the spirit of the present disclosure.

Terms used herein are intended to describe specific embodiments and are not intended to limit the present disclosure. In addition, in the present specification, singular forms may include plural forms unless the context clearly indicates otherwise.

In the description of the embodiment, when each layer (film), area, pattern, or structure is described as being formed “on” or “under” a substrate, each layer (film), area, pad, or patterns, “on” and “under” include both cases of being formed “directly” or “indirectly with other elements interposed therebetween.” In addition, in principle, the reference for “above” or “under” each layer are based on the drawing.

The drawings are only intended to help understanding of the spirit of the present disclosure and should not be construed as limiting the scope of the present disclosure by the drawings. In addition, in the drawings, a relative thickness and length, or a relative size may be exaggerated for convenience and clarity of description.

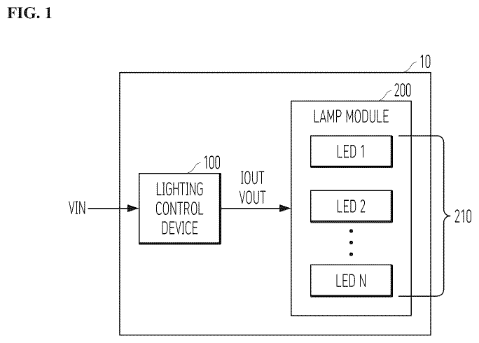

FIG. 1 shows a lighting device according to embodiments of the present disclosure. Referring to FIG. 1, a lighting device 10 may include a lighting control device 100 and a lamp module 200.

The lighting device 10 may be a device configured to emit light using electricity. For example, the lighting device 10 may be a lighting device such as a streetlight or tunnel light including a light emitting element, but embodiments of the present disclosure are not limited thereto. In addition, for example, the lighting device 10 may be an LED lighting device including a light emitting diode (LED) element, but the embodiments of the present disclosure are not limited thereto.

The lighting device 10 may output light according to input power VIN supplied from the outside. For example, the lighting device 10 may receive the input power VIN through a power line.

The brightness of the lighting device 10 according to the embodiments of the present disclosure may be changed. That is, the lighting device 10 may perform brightness control (i.e., dimming). According to the embodiments, the lighting device 10 may perform dimming according to a dimming level signal input from the outside, but is not limited thereto.

The lighting device 10 may include the lighting control device 100 and the lamp module 200.

The lighting control device 100 is a device for controlling the overall operation of the lighting device 10 and may include at least one electronic circuit.

The lighting control device 100 may convert the input power VIN input from the outside to generate output power and supply the output power to the lamp module 200. Therefore, the lamp module 200 may emit light, and the lighting device 10 may emit light.

According to the embodiments, the lighting control device 100 may generate the output power in a DC waveform from the input power VIN in an AC waveform, and output generated output power IOUT to the lamp module 200. In this case, the input power is commercial power and may be an AC voltage in which a frequency is 60 Hz and an amplitude is 220 V. For example, the lighting control device 100 may include a converter.

The lamp module 200 may emit light based on the supplied output power IOUT. According to the embodiments, the lamp module 200 may include LED elements 210 each capable of emitting light by itself, but is not limited thereto, and the LED elements 210 may be replaced with a halogen lamp or a sodium lamp.

The LED elements 210 may be connected in series or parallel, and the driving voltage of the LED elements 210, that is, the lamp module 200 may be determined by the rated voltage and flowing current of all of the LED elements 210 connected to each other.

Meanwhile, as described above, the lighting device 10 may perform dimming in which brightness changes over time. The brightness of the lighting device 10 may be based on the brightness of the lamp module 200, which is a light source, and the brightness of the lamp module 200 may be based on the intensity of the operating power IOUT output from the lighting control device 100. Therefore, to control dimming, the lighting control device 100 may adjust the intensity of the operating power IOUT within the range from the minimum level to the maximum level.

Meanwhile, the lighting control device 100 may receive a dimming level signal having a level in a specific range and perform dimming of the lighting device 10 in response to the dimming level signal. For example, the dimming level signal may be a voltage or a pulse width modulation (PWM) signal having a value between 0 V and 10 V, but the embodiments of the present disclosure are not limited thereto.

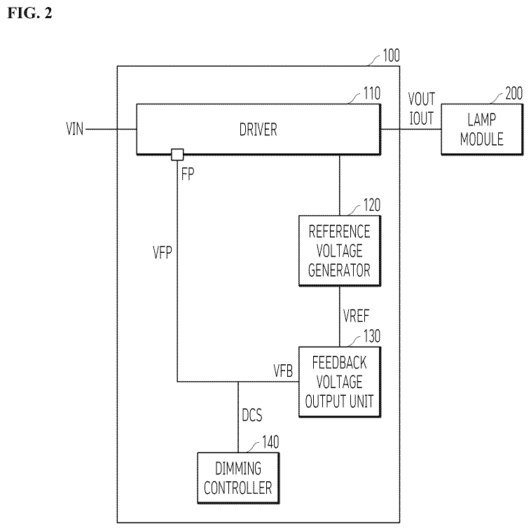

FIG. 2 shows a lighting control device according to the embodiments of the present disclosure. Referring to FIG. 2, the lighting control device 100 may include a driver 110, a reference voltage generator 120, a feedback voltage output unit 130, and a dimming controller 140.

The driver 110 may receive the input power VIN from the outside and output the output power VOUT or IOUT for driving the lamp module 200 to the lamp module 200 using the input power VIN. According to the embodiments, the driver 110 may appropriately convert AC input power VIN to generate the DC output power VOUT or IOUT. For example, the driver 110 may include a switching element, such as a transistor, and generate the output power VOUT or IOUT from the input power VIN using a switching operation of the switching element.

The driver 110 may include a feedback pin FP and adjust the output power VOUT or IOUT based on a voltage applied to the feedback pin FP, that is, a feedback pin voltage VFP. For example, the driver 110 may adjust the magnitudes of the output power VOUT or IOUT based on the feedback pin voltage VFP.

The reference voltage generator 120 may output a reference voltage VREF. According to the embodiments, the reference voltage generator 120 may be electrically connected to the driver 110 to receive the operating power required for operating the reference voltage generator 120 from the driver 110. In this case, the operating power may be transmitted from a secondary winding of a transformer 113.

The reference voltage VREF output by the reference voltage generator 120 may be an independent voltage not linked to the output voltage VOUT. That is, there may be a voltage section in which the reference voltage VREF and the output voltage VOUT are not changed in the same direction. For example, even when the output voltage VOUT is changed within a predetermined range, the reference voltage VREF may not be changed. For example, the reference voltage generator 120 may be a step-down converter, but is not limited thereto.

As described above, the reference voltage generator 120 uses the output voltage VOUT as an operating power source and does not generate the reference voltage VREF through conversion such as step-up or step-down of the output voltage VOUT.

The feedback voltage output unit 130 may output a feedback voltage VFB. According to the embodiments, the feedback voltage output unit 130 may be electrically connected to the feedback pin FP of the driver 110, and the feedback voltage VFB output by the feedback voltage output unit 130 may be connected to the feedback pin FP.

The feedback voltage output unit 130 may receive the reference voltage VREF from the reference voltage generator 120 and output the feedback voltage VFB using the reference voltage VREF. According to the embodiments, the feedback voltage VFB may be linked to the reference voltage VREF. That is, there may be a voltage section in which the feedback voltage VFB and the reference voltage VREF are changed in the same direction.

The feedback voltage output unit 130 may output the feedback voltage VFB that is smaller than a threshold voltage. For example, the feedback voltage VFB may have a constant magnitude during an operation of the lighting control device 100, but is not limited thereto.

The dimming controller 140 may output a dimming control signal DCS for adjusting the brightness of the lamp module 200 according to the dimming operation. According to the embodiments, the dimming controller 140 may receive the dimming level signal and output the dimming control signal DCS based on the dimming level signal. In this case, the dimming level signal may be input from the outside, but is not limited thereto.

The dimming controller 140 may compare a dimming level (i.e., a current dimming level) indicated by the magnitude of the driving current IOUT with a dimming level (i.e., a target dimming level) indicated by the dimming level signal and output the dimming control signal DCS according to the result of the comparison.

The dimming control signal DCS output from the dimming controller 140 may be output to the feedback pin FP. According to the embodiments, the dimming controller 140 may be connected to the feedback voltage output unit 130 and the driver 110. Therefore, the feedback pin voltage VFP is determined based on both the feedback voltage VFB and the dimming control signal DCS.

Since the feedback voltage VFB is output as a fixed value, the feedback pin voltage VFP may be changed according to the dimming control signal DCS, and such a change leads to the adjustment of the output current IOUT of the driver 110. Therefore, as a result, the magnitude of the output current IOUT may be adjusted through the dimming controller 140, and a dimming operation in which the brightness of the lamp module 200 is changed may be performed.

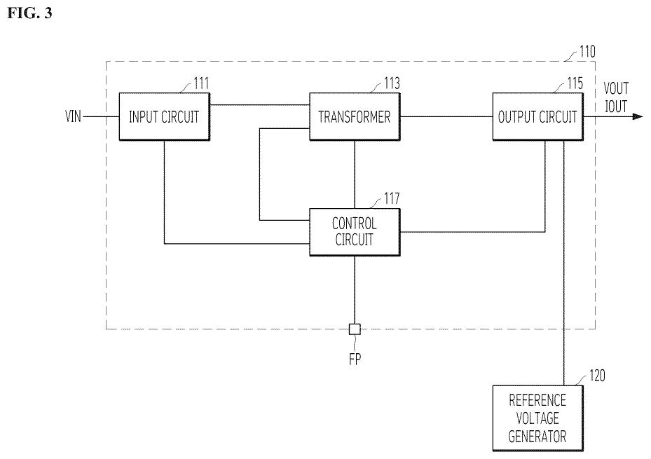

FIG. 3 shows a driver according to the embodiments of the present disclosure. Referring to FIG. 3, the driver 110 may include an input circuit 111, a transformer 113, an output circuit 115, and a control circuit 117.

The input circuit 111 may receive the input power VIN. The input circuit 111 may include a rectifier circuit for rectifying the input power VIN. The rectifier circuit may include a diode and/or capacitor, but is not limited thereto. For example, the input circuit 111 rectifies the AC current input power VIN, converts the AC current input power into direct current input power, and outputs the rectified voltage. The rectified voltage may be transmitted to the control circuit 117.

According to the embodiments, a filter circuit for removing noise of the input power VIN or a voltage stabilization circuit for stabilizing the input power VIN may be provided at a front end of the input circuit 111.

For example, the voltage stabilization circuit is a circuit for protecting internal components by blocking an overvoltage or overcurrent introduced from the input power VIN side and may be, for example, a snubber circuit, but is not limited thereto. When receiving the overcurrent or the overvoltage as the input power VIN, the voltage stabilization circuit may include a fuse for blocking the overcurrent or the overvoltage and/or a varistor for blocking the input overvoltage, but the embodiments of the present invention are not limited thereto.

The transformer 113 may include at least two windings facing each other, and power applied to any one of the windings may be transmitted to the other through an electromagnetic induction phenomenon. For example, the transformer 113 may convert the power input to a primary winding at a predetermined ratio and output (transmit) the converted power through a secondary winding facing the primary winding. Upon transmission, the magnitude of the power may be changed according to the number of turns between the two windings.

The output circuit 115 may be connected to the transformer 113 to convert the power output from the secondary winding of the transformer 113 and output the output power VOUT or IOUT to the lamp module 200. According to the embodiments, the output circuit 115 may include a rectifier circuit for rectifying the power transmitted from the secondary winding. The rectifier circuit may include a diode and/or capacitor, but is not limited thereto. That is, the output power VOUT or IOUT may be a DC.

The control circuit 117 may generally control the operation of the driver 110. The control circuit 117 may be an integrated circuit including a plurality of elements and logic gates, but is not limited thereto.

The control circuit 117 may include a switching element such as a transistor, convert a rectified voltage into a pulse by periodically turning on and off the rectified voltage transmitted from the input circuit 111 according to the switching operation of the switching element, and transmit the pulsed rectified voltage to the transformer 113. The pulsed rectified voltage transmitted to the transformer 113 is transformed according to a predetermined turns ratio and transmitted to the output circuit 115.

In this case, the magnitude of the voltage transmitted to the output circuit 115, that is, the magnitude of the output voltage VOUT is determined according to a length of a section in which the rectified voltage is turned on by the switching element.

The control circuit 117 may control the output of the driver 110 by controlling the switching operation of the switching element. According to the embodiments, the control circuit 117 may adjust the magnitude of the output voltage VOUT of the driver 110 by adjusting a cycle (i.e., a duty) of the switching operation.

The control circuit 117 may control the driver 110 so that the output power VOUT or IOUT is maintained within a predetermined driving range. It is referred to as a feedback operation. It is possible to ensure the stable operation of the lamp module 200 connected to the lighting control device 100 and at the same time, ensure the safety of internal components of the lighting control device 100.

According to the embodiments, the control circuit 117 may perform the feedback operation by adjusting the magnitude of the output power VOUT or IOUT based directly or indirectly on the output power VOUT or IOUT. For example, when the output power VOUT or IOUT becomes excessively high, the output power VOUT or IOUT may decrease according to the feedback operation, and vice versa.

For example, the control circuit 117 may perform the feedback operation on the output voltage VOUT by controlling the cycle of the switching operation of the switching element based directly or indirectly on the output power VOUT or IOUT. In addition, the control circuit 117 may perform the feedback operation on the output current IOUT by supplying a predetermined leakage current to the output terminal of the output circuit 115 based directly or indirectly on the output power VOUT or IOUT.

According to the embodiments of the present disclosure, the control circuit 117 may adjust the output IOUT or VOUT of the driver 110 according to the magnitude of the feedback pin voltage VFP applied to the feedback pin FP. According to the embodiments, the control circuit 117 may increase, maintain, or decrease the magnitude of the output power VOUT or IOUT according to the magnitude of the feedback pin voltage VFP.

The control circuit 117 may compare the feedback pin voltage VFP with a predetermined threshold voltage and adjust the output IOUT or VOUT according to the result of the comparison. For example, the control circuit 117 may reduce the magnitude of the output power VOUT or IOUT when the feedback pin voltage VFP exceeds the predetermined threshold voltage. In addition, the control circuit 117 may increase the magnitude of the output power VOUT or IOUT when the feedback pin voltage VFP is smaller than the threshold voltage. In addition, the control circuit 117 may maintain the magnitude of the output power VOUT or IOUT when the feedback pin voltage VFP is substantially the same as the predetermined threshold voltage.

Meanwhile, according to the embodiments, the control circuit 117 may stop at least a portion of the output of the driver 110 when the feedback pin voltage VFP is out of a predetermined feedback allowable range. For example, when the feedback pin voltage VFP is out of the feedback allowable range, the control circuit 117 may adjust the output power VOUT or IOUT to be a predetermined minimum voltage or less. In this case, the lowest voltage may be a voltage at which the lamp module 200 may not normally emit light, that is, a value out of a rated voltage range. For example, the lowest voltage may be zero, but is not limited thereto.

That is, the control circuit 117 may adjust the output power VOUT or IOUT so that the lamp module 200 is turned off when the feedback pin voltage VFP is out of the feedback allowable range. Therefore, in order for the lighting control device 100 to normally control the light emission of the lamp module 200, the feedback pin voltage VFP needs to be within the feedback allowable range.

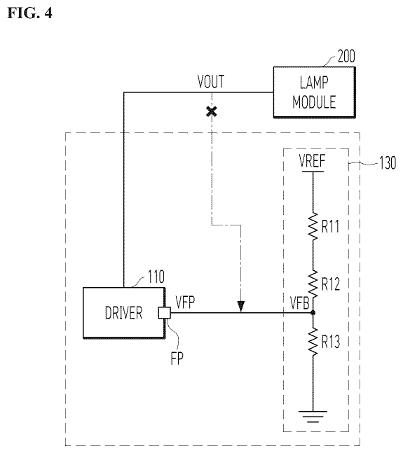

FIG. 4 is a view for describing an operation of a feedback voltage output unit according to the embodiments of the present disclosure. Referring to FIG. 4, the feedback voltage output unit 130 outputs the feedback voltage VFB, and the output feedback voltage VFB is transmitted to the feedback pin FP. That is, in FIG. 4, the feedback pin voltage VFP directly becomes the feedback voltage VFB.

The feedback voltage output unit 130 may generate the feedback voltage VFB using the reference voltage VREF. For example, the feedback voltage output unit 130 may be a voltage division circuit for generating the feedback voltage VFB by dividing the reference voltage VREF through a plurality of resistors R11, R12, and R13, but is limited thereto, which may be any type of circuit for generating the feedback voltage VFB using the reference voltage VREF.

Meanwhile, the reference voltage VREF according to the embodiments of the present disclosure is a voltage unrelated to the output voltage VOUT applied to the lamp module 200. That is, even when the magnitude of the output voltage VOUT is changed, the magnitude of the feedback voltage VFB may not be changed.

The lighting control device such as the conventional converter generates a feedback voltage from the output voltage through a method such as voltage division and adjusts the output by controlling the switching operation of the converter using the generated feedback voltage. Since the output voltage is determined according to the rated voltage of the lamp module, the feedback voltage of the converter is also eventually determined according to the rated voltage.

Therefore, when the conventional lighting device is manufactured, the feedback voltage of the converter is set to be within the allowable feedback range in consideration of the rated voltage range of the lamp module. However, when the rated voltage is lower than the conventional lamp module due to replacement with a high-efficiency lamp module, etc., the feedback voltage applied to the conventional converter may be out of the feedback tolerance range (e.g., smaller than the lower limit of the feedback allowable range, etc.), and thus the convention converter may have a problem that the replaced high-efficiency lamp module may not be operated normally.

On the other hand, since the lighting control device 100 according to the embodiments of the present disclosure separately generates and uses the feedback voltage VFB unrelated to the output voltage VOUT, the feedback voltage VFB is not changed even upon replacement with the high-efficiency lamp module, and thus the lighting control device 100 may normally drive the lamp module 200. Therefore, the lighting device provided with the lighting control device according to the embodiments of the present disclosure may use the conventional lighting control device even when the lamp module is replaced, which is economically effective.

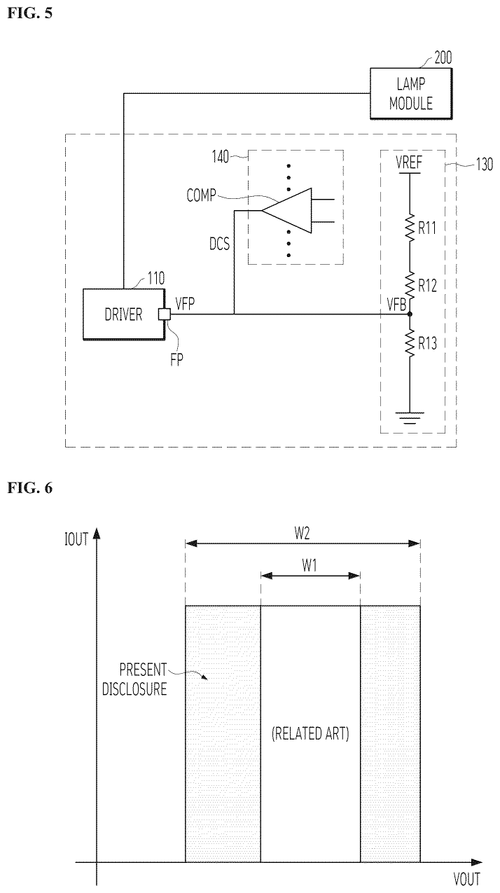

FIG. 5 is a view for describing an operation of a dimming controller according to the embodiments of the present disclosure. Referring to FIG. 5, the dimming controller 140 outputs the dimming control signal DCS according to the dimming operation.

According to the embodiments, the dimming controller 140 may compare the target dimming level with the current dimming level in response to the dimming level signal and output the dimming control signal DCS according to the result of the comparison.

The dimming control signal DCS may be applied to the feedback pin FP together with the feedback voltage VFB. Therefore, the magnitude of the feedback pin voltage VFP may be changed according to the feedback voltage VFB and the dimming control signal DCS. Since a change in magnitude of the feedback pin voltage VFP causes the driver 110 to adjust the output current IOUT, the brightness of the lamp module 200 may be eventually adjusted through the dimming control signal DCS.

For example, when the current dimming level corresponding to the driving current IOUT exceeds the target dimming level (i.e., current brightness>target brightness), the dimming controller 140 may output the dimming control signal DCS having a positive voltage value. In this case, the magnitude of the dimming control signal DCS may be determined so that the feedback pin voltage VFP determined by the feedback voltage VFB and the dimming control signal DCS exceeds a threshold voltage VTH.

Therefore, when the dimming control signal DCS is output, the feedback pin voltage VFP exceeds the threshold voltage VTH, and the driver 110 performs the adjustment operation of reducing the driving current IOUT in response to the feedback pin voltage VFP exceeding the threshold voltage VTH. As a result, the brightness of the lamp module 200 can be decreased, thereby achieving the target dimming level.

In addition, for example, the dimming controller 140 may not output the dimming control signal DCS when the dimming level corresponding to the driving current IOUT is smaller than the target dimming level (i.e., current brightness<target brightness).

Therefore, the feedback pin voltage VFP becomes the feedback voltage VFB smaller than the threshold voltage VTH, and the driver 110 increases the driving current IOUT. As a result, the brightness of the lamp module 200 can be increased, thereby achieving the target dimming level.

According to the embodiments, the dimming controller 140 may include a comparator COMP for comparing the current dimming level with the target dimming level. For example, a signal related to the target dimming level may be input to a negative input terminal of the comparator COMP, a signal related to the current dimming level may be input to a positive input terminal, and the comparator COMP may output the dimming control signal DCS to the output terminal through the comparison operation.

As described above, the lighting control device 100 of the embodiments of the present disclosure may indirectly control the brightness of the lamp module 200 by adjusting the magnitude of the feedback pin voltage VFP through the dimming controller.

FIG. 6 is a view for describing the effect of the lighting control device according to the embodiments of the present disclosure. As described with reference to FIGS. 1 to 5, since the lighting control device 100 according to the embodiments of the present disclosure separately generates and uses the feedback voltage VFB unrelated to the output voltage VOUT, the lighting control device 100 may drive the lamp module 200 without any significant restriction to the rated voltage of the lamp module 200. That is, there is an effect of expanding the range of the output voltage VOUT of the lighting control device 100.

As shown in FIG. 6, since the lighting control device such as the conventional converter uses the feedback voltage linked to the rated voltage of the conventional mounted lamp module, the lighting control device is operated within the limited range of the output voltage VOUT corresponding to the rated voltage of the lamp module, and thus has a relatively narrow output voltage range W1.

On the other hand, as described above, the lighting control device 100 according to the embodiments of the present disclosure may normally drive the lamp module even in a range other than the output voltage VOUT corresponding to the rated voltage of the lamp module, and thus have a relatively wide output voltage range W2.

Furthermore, the lighting control device 100 according to the embodiments of the present disclosure can also perform the dimming control by changing the output current IOUT within the output voltage range like the conventional lighting control device.

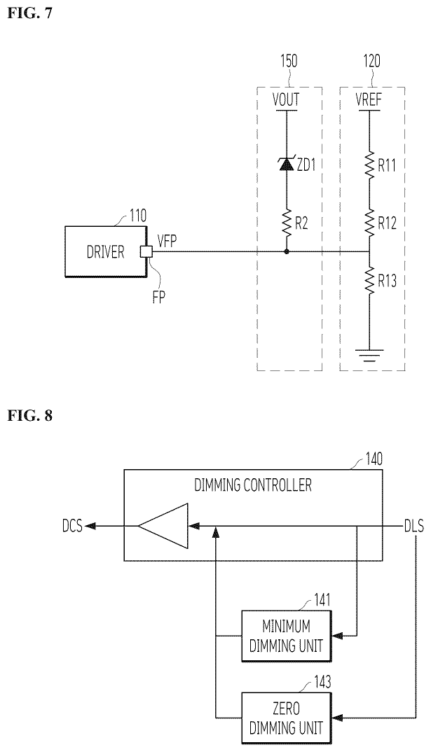

FIG. 7 shows a maximum output fixing unit according to the embodiments of the present disclosure. Referring to FIG. 7, the lighting control device 100 may further include a maximum output fixing unit 150.

The maximum output fixing unit 150 may be connected between the driver 110 and the feedback voltage output unit 130. The maximum output fixing unit 150 can protect the internal components of the lighting device 10 by preventing the output power VOUT or IOUT applied to the lamp module 200 from exceeding a predetermined maximum value.

When the connection between the driver 110 and the lamp module 200 is open, the driving current IOUT becomes zero, and thus the current dimming level corresponding to the driving current IOUT becomes the lowest. Therefore, the dimming controller 140 may not output the dimming control signal DCS, and as a result, the feedback voltage VFB is smaller than the threshold voltage VTH, and thus the driver 110 continuously performs the feedback operation of increasing the driving power IOUT or VOUT. Therefore, the driving power IOUT or VOUT may continuously increase, resulting in a problem in which the internal components of the lighting control device 100 are damaged due to an overvoltage, etc.

When the output voltage VOUT is a predetermined maximum (e.g., a maximum allowable output voltage) or higher, the maximum output fixing unit 150 may output an output fixing signal OFS to the feedback pin FP, and thus the feedback pin voltage VFP becomes substantially the same as the threshold voltage VTH or becomes the threshold voltage VTH or higher so that the driver 110 may not increase the driving power VOUT or IOUT anymore. For example, the output fixing signal OFS may be added to the feedback voltage VFB to increase the feedback pin voltage VFP.

The output fixing signal OFS may be directly output to the feedback pin FP or transmitted to the feedback voltage output unit 130 and indirectly output to the feedback pin FP.

According to the embodiments, the maximum output fixing unit 150 may include at least one Zener diode ZD1 and at least one resistor R2 connected to the output terminal of the driver 110, but is not limited thereto.

In this case, when the output voltage VOUT is applied to the Zener diode ZD1 and the output voltage VOUT exceeds a breakdown voltage of the Zener diode ZD1, the Zener diode ZD1 electrically conducts to allow the output fixing signal OFS corresponding to at least some of the output voltages VOUT to be applied to the feedback pin FP through the resistor R2, and as a result, the feedback pin voltage VFP is increased.

In this case, the breakdown voltage of at least one Zener diode ZD1 may be smaller than or equal to the maximum allowable output voltage (or the maximum value of the rated voltage) of the lamp module 200.

FIG. 8 shows a minimum dimming unit and a zero dimming unit according to the embodiments of the present disclosure. Referring to FIG. 8, the lighting control device 100 may include a minimum dimming unit 141 and a zero dimming unit 143. According to the embodiments, the lighting control device 100 may selectively include only any one of the minimum dimming unit 141 and the zero dimming unit 143.

The dimming control circuit 140 may output the dimming control signal DCS for controlling the brightness of the lamp module 200 according to the target dimming level indicated by a dimming level signal DLS. For example, the dimming control circuit 140 may compare the current dimming level with the target dimming level and output the dimming control signal DCS.

The minimum dimming unit 141 and the zero dimming unit 143 may be connected to an input line to which the dimming level signal DLS is input. According to the embodiments, the minimum dimming unit 141 and the zero dimming unit 143 may adjust the voltage of the level input line by outputting the output signal to the corresponding input line based on the voltage of the level input line to which the dimming level signal DLS is input. Therefore, the dimming control signal DCS output from the dimming controller 140 may be indirectly adjusted.

The minimum dimming unit 141 is a circuit for setting the minimum brightness of the lighting device 10 or the lamp module 200. According to the embodiments, the minimum dimming unit 141 may compare the voltage of the level input line with a predetermined lowest dimming level, and when the voltage of the level input line is smaller than or equal to the lowest dimming level according to the result of the comparison, output the voltage signal corresponding to the lowest dimming level to the level input line.

Therefore, the voltage of the level input line to which the dimming level signal DLS of the dimming controller 140 is input according to the minimum dimming unit 141 is maintained at least at the level of the lowest dimming level, and as a result, the brightness of the lamp module 200 can also be maintained at the brightness or more corresponding to the lowest dimming level.

In the case of a space such as a tunnel, there is a problem that the minimum brightness of the lighting device 10 should be secured, and in this case, it is possible to secure the minimum brightness of the lighting device 10 using the minimum dimming unit 141.

The zero dimming unit 143 is a circuit for setting the brightness of the lighting device 10 or the lamp module 200 to zero, that is, turning the lighting device 10 or the lamp module 200 off. According to the embodiments, the zero dimming unit 143 may compare the dimming level of the dimming level signal DLS with the predetermined zero dimming level, and when the dimming level of the dimming level signal DLS is smaller than or equal to the zero dimming level according to the result of the comparison, output the voltage corresponding to the zero dimming voltage, that is, the voltage signal at the ground level to the level input line.

Therefore, when the level of the dimming level signal DLS is smaller than or equal to the predetermined zero dimming level, it is considered to indicate turn-off (i.e., full black out) of the lamp module 200, and thus the voltage of the level input line becomes substantially a ground level by the zero dimming unit 143. Therefore, the dimming controller 140 may control the lamp module 200 to be turned off.

As described above, the dimming controller 140 controls the brightness of the lamp module 200 based on the voltage of the level input line to which the dimming level signal DLS is input, and even when the dimming level of the dimming level signal DLS is the zero dimming level by external factors such as circuit elements inside the dimming controller 140, there is a case where the voltage of the corresponding level input line does not correspond to the zero dimming level and is maintained at a slightly higher level. In this case, by using the zero dimming unit 143, the voltage of the level input line can be maintained at the ground level, and thus the brightness of the lamp module 200 may be adjusted to the zero dimming level.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed according to the appended claims, and all technical spirits within the equivalent range should be construed as being included in the scope of the present disclosure.

The above-described device (unit) may be implemented as a hardware element and/or a software element. For example, the hardware element may include a microphone, an amplifier, a bandpass filter, an A/D converter, and a processing device. The processing device may be implemented by using one or more general-purpose or special-purpose computers such as include, for example, a processor, a controller, an arithmetic logic unit (ALU), a digital signal processor, a microcomputer, a field programmable gate array (FPGA), a programmable logic unit (PLU), a microprocessor, or other devices capable of responding to and executing instructions in a defined manner. The processing device may run an operating system (OS) and one or more software applications running on the operating system. In addition, the processing device may access, store, manipulate, process, and generate data in response to the execution of software. For simple description, the processing device may be described as one, but those skilled in the art can know that the processing device may include multiple processing elements and/or multiple types of processing elements. For example, the processing device may include a plurality of processors or a processor and a controller. In addition, other processing configurations, such as parallel processors, are possible.

Software may include computer programs, code, instructions, or combinations thereof, which may independently or collectively configure or instruct the processing device to operate as desired. The software and data may be expressed as propagated signal waves that may be interpreted by and may provide instructions or data to a processing device, or may be embodied permanently or temporarily in various types of machines, components, physical devices, virtual devices, computer storage media or devices, etc. The software may be distributed over networked computer systems and thus stored and executed in a distributed manner. The software and data may be stored in one or more computer-readable recording media, which includes a data storage device for storing data and then readable by the computer system or the processing device. A method according to the embodiment may be implemented in a form of program instructions that may be performed through various computer devices and recorded on a computer-readable medium. Examples of computer-readable recording media include a ROM, a RAM, a CD-ROM, a magnetic tape, a floppy disk, and an optical data storage device. Examples of the computer-readable recording medium include magnetic media such as a hard disk, a floppy disk, and a magnetic tape, optical media such as a CD-ROM and a DVD, and magneto-optical media such as a floptical disk, and hardware devices specifically configured to store and execute program instructions, such as a ROM, a RAM, and a flash memory. In addition, the functional programs, code, and code segments that complete the examples disclosed herein can be easily understood and implemented by a programmer having ordinary skill in the art related to these examples based on or using the flowchart and block diagrams of the drawings and the related descriptions provided herein.

Although not universal, the terminals or devices described herein may be applied to mobile devices such as a cellular phone, a PDA, a digital camera, a portable game console, an MP3 player, a portable/personal multimedia player (PMP), a portable e-book, a portable laptop PC, a GPS navigation system, a tablet PC, and a sensor, a desktop PC, a HDTV, an optical disc player, a set-top box, home appliance, and devices capable of wireless or network communication.

In addition, the computer-readable medium may include program instructions, data files, data structures, etc. alone or in combination. The program instructions recorded on the medium may be specially designed and constructed for the embodiments or may be known and available to those skilled in the art of computer software. Examples of the program instructions include not only machine language code such as that produced by a compiler but also high-level language code that may be executed by a computer using an interpreter, etc. The hardware device may be configured to operate as one or more software modules to perform the operation of the embodiments, and vice versa.

Although several embodiments have been described above, it should be understood that various modifications can be made. For example, appropriate results may be achieved even when the techniques described are performed in a different order and/or elements of the stated system, structure, device, circuit, etc. are coupled in a different way or replaced with or supplemented by other elements or equivalents. Therefore, other implementations also fall within the scope of the appended claims.

1. A lighting control device connected to a lamp module and configured to control light emission of the lamp module, comprising:
a driver configured to receive input power, output output power to the lamp module, and adjust a magnitude of the output power according to the result of comparison between a feedback pin voltage applied to a feedback pin and a threshold voltage;
a feedback voltage output unit configured to output a feedback voltage unrelated to the output power to the feedback pin; and
a dimming controller configured to receive a dimming level signal and output a dimming control signal for controlling the brightness of the lamp module to the feedback pin based on a target dimming level corresponding to the dimming level signal and a current dimming level corresponding to a current brightness of the lamp module.

2. The lighting control device of claim 1, wherein the feedback voltage output unit outputs the feedback voltage smaller than the threshold voltage.

3. The lighting control device of claim 1, wherein the driver increases the output power in response to the feedback pin voltage smaller than the threshold voltage.

4. The lighting control device of claim 1, wherein the driver decreases the output power in response to the feedback pin voltage exceeding the threshold voltage.

5. The lighting control device of claim 1, wherein the driver adjusts the output power to turn the lamp module off in response to the feedback pin voltage out of a feedback allowable range.

6. The lighting control device of claim 1, wherein the dimming controller outputs the dimming control signal having a positive voltage value to the feedback pin so that the feedback pin voltage exceeds the threshold voltage when the current dimming level exceeds the target dimming level.

7. The lighting control device of claim 1, wherein the driver includes:
an input circuit configured to rectify the input power and generate a rectified voltage;
a control circuit including a switching element and configured to transform the rectified voltage into a pulse according to a switching operation of the switching element to output the pulsed rectified voltage;
a transformer configured to transform the pulsed rectified voltage transmitted to a primary winding and transmit the transformed rectified voltage to a secondary winding; and
an output circuit configured to generate the output power using a voltage transmitted from the secondary winding of the transformer.

8. The lighting control device of claim 7, wherein the lighting control device further includes a reference voltage generator configured to generate a reference voltage unrelated to the output power and output the reference voltage using the voltage transmitted from the secondary winding of the transformer as operating power, and
the feedback voltage output unit outputs the feedback voltage associated with the reference voltage using the reference voltage.

9. The lighting control device of claim 1, wherein the lighting control device further includes a maximum output fixing unit configured to output an output fixing signal that allows the feedback pin voltage to become the threshold voltage or higher to the feedback pin when the output power is greater than or equal to a predetermined maximum allowable value.

10. The lighting control device of claim 9, wherein the maximum output fixing unit includes at least one Zener diode that has one end which is connected to an output terminal of the driver and to which the output power is input and the other end connected to an output terminal of the feedback voltage output unit, and
is electrically conducted selectively according to a magnitude of the output power.
